(19) United States
(12) Patent Application Publication
(10) Pub. No.: US 2025/0316566 A1
(43) Pub. Date: Oct. 9, 2025

(54) ENCAPSULATED PACKAGE WITH CARRIER HAVING RETRACTED LATERAL EXTENSION LATERALLY COVERED BY ENCAPSULANT

(71) Applicant: Infineon Technologies AG, Neubiberg (DE)

(72) Inventor: Aira Lourdes Baring VILLAMOR, Melaka (MY)

(73) Assignee: Infineon Technologies AG, Neubiberg (DE)

(21) Appl. No.: 19/052,580

(22) Filed: Feb. 13, 2025

(30) Foreign Application Priority Data
Apr. 4, 2024 (DE) 10 2024 203 095.3

(51) Int. Cl. H01L 23/495; H01L 21/48; H01L 21/56; H01L 23/00; H01L 23/31; H10D 80/20

(52) U.S. Cl. CPC H01L 23/49562; H01L 21/4842; H01L 21/561; H01L 23/3157; H01L 23/49503; H01L 24/08; H01L 24/96; H01L 24/97; H01L 2224/08245; H01L 2224/96; H01L 2224/97; H01L 2924/1815; H10D 80/231; H10D 80/251

(57) ABSTRACT

A package and method is disclosed. In one example, the package includes a carrier comprising a component mounting area from which a lateral extension extends, the lateral extension being configured for being clamped by an encapsulant tool pin during encapsulation, an electronic component mounted on the component mounting area, and an encapsulant encapsulating at least part of the electronic component and part of the carrier. The lateral extension is laterally retracted with respect to a neighboring vertical sidewall of the encapsulant. The encapsulant laterally covers the lateral extension.

### CROSS-REFERENCE TO RELATED APPLICATION

This Utility Patent Application claims priority to German Patent Application No. 10 2024 203 095.3 filed Apr. 4, 2024, which is incorporated herein by reference.

### BACKGROUND

### Technical Field

Various embodiments relate generally to a package, and a method of manufacturing a package.

### Description of the related art

Packages may be denoted as encapsulated electronic components with electrical connections extending out of the encapsulant and being mountable on an electronic periphery, for instance on a printed circuit board.

Packaging cost is an important driver for the industry. Related with this are performance, dimensions and reliability. The different packaging solutions are manifold and have to address the needs of the application.

### Summary

There may be a need to provide a possibility to manufacture packages with high device reliability and in a simple and quick way.

According to an exemplary embodiment, a package is provided which comprises a carrier comprising a component mounting area from which a lateral extension extends, the lateral extension being configured for being clamped by an encapsulant tool pin during encapsulation, an electronic component mounted on the component mounting area, and an encapsulant encapsulating at least part of the electronic component and part of the carrier, wherein the lateral extension is laterally retracted with respect to a neighboring vertical sidewall of the encapsulant, and wherein the encapsulant laterally covers the lateral extension.

According to another exemplary embodiment, a method of manufacturing a package is provided, wherein the method comprises providing a carrier comprising a component mounting area from which a lateral extension extends, mounting an electronic component on the component mounting area, encapsulating at least part of the electronic component and part of the carrier by an encapsulant, wherein the lateral extension is clamped by an encapsulant tool pin during at least part of the encapsulating, and adjusting the encapsulating so that the lateral extension is laterally retracted with respect to a neighboring vertical sidewall of the encapsulant, and so that the encapsulant laterally covers the lateral extension.

According to an exemplary embodiment, an encapsulated (in particular molded) package is provided which has a carrier (which may be made for instance of a metallic material, in particular based on a leadframe structure) with a component mounting area (such as a die pad) carrying at least one electronic component (such as a semiconductor chip). At least one lateral extension may extend laterally from the component mounting area. The lateral extension may be used to be clamped down by an encapsulant tool pin during the process of encapsulating carrier and electronic component by an encapsulant (such as a mold compound). This clamping of the lateral extension together with the component mounting area of the carrier may prevent an undesired flow of still flowable encapsulant to the bottom side of the carrier which may allow to avoid undesired phenomena such as mold flash or bleeding of encapsulant material into unintentional regions of the package. Advantageously, the lateral extension may be laterally retracted with respect to a neighboring (in particular exterior or outermost) vertical sidewall (which may be defined by a sawing process) of the encapsulant. Consequently, a process of separating the package from other packages during a batch manufacturing process may be simplified, since no sawing through (in particular metallic material) of the lateral extension may be necessary. This may significantly accelerate and simplify the singulation process. When such a sawing process extends substantially only through encapsulant material (and optionally through one or more optional tiny tie pads), this may lead to a configuration in which the encapsulant laterally covers the lateral extension and therefore provides a sideways buffer between lateral extension and vertical sidewall of the package. As a result, undesired burrs may be reliably prevented at the package's sidewalls, which may be generated when sawing through the lateral extension. Due to the described package architecture, artefacts such as mold flash and/or burrs may be efficiently suppressed, while simultaneously allowing a simple and efficient manufacture of the package. As a result, packages may be provided which can be manufactured with high device reliability and in a simple and quick way.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a three-dimensional view of a package according to an exemplary embodiment.

FIG. 2 illustrates a plan view of the package according to FIG. 1.

FIG. 3 illustrates a three-dimensional front view of a structure obtained during manufacturing a package according to FIG. 1 and FIG. 2.

FIG. 4 illustrates a three-dimensional back view of a structure obtained during manufacturing a package according to FIG. 1 and FIG. 2.

FIG. 5 illustrates a three-dimensional back view of a package according to another exemplary embodiment.

FIG. 6 illustrates a three-dimensional front view of the package according to FIG. 5.

FIG. 7 illustrates a three-dimensional front view of a structure obtained during manufacturing a package according to FIG. 5 and FIG. 6.

FIG. 8 illustrates a three-dimensional back view of a structure obtained during manufacturing a package according to FIG. 5 and FIG. 6.

FIG. 9 illustrates a three-dimensional back view of a package according to another exemplary embodiment.

FIG. 10 illustrates a three-dimensional front view of the package according to FIG. 9.

FIG. 11 illustrates a three-dimensional front view of a structure obtained during manufacturing a package according to FIG. 9 and FIG. 10.

FIG. 12 illustrates a three-dimensional back view of a structure obtained during manufacturing a package according to FIG. 9 and FIG. 10.

FIG. 13 illustrates a plan view of a structure obtained during manufacturing a package according to an exemplary embodiment.

FIG. 14 illustrates different views of a package obtained from a structure according to FIG. 13.

FIG. 15 illustrates a three-dimensional back view of a part of the structure according to FIG. 13.

FIG. 16 illustrates a side view and a plan view of a structure obtained during manufacturing a package according to an exemplary embodiment.

FIG. 17 illustrates different views of a package obtained from a structure according to FIG. 16.

FIG. 18 illustrates a three-dimensional back view of a structure obtained during manufacturing a package according to an exemplary embodiment.

FIG. 19 illustrates a package obtained from the structure according to FIG. 18.

FIG. 20 illustrates a three-dimensional back view of a structure obtained during manufacturing a package according to an exemplary embodiment.

FIG. 21 illustrates a three-dimensional front view of the structure according to FIG. 20.

FIG. 22 illustrates a flowchart of a method of manufacturing a package according to an exemplary embodiment.

### DETAILED DESCRIPTION

There may be a need to provide a possibility to manufacture packages with high device reliability and in a simple and quick way.

According to an exemplary embodiment, a package is provided which comprises a carrier comprising a component mounting area from which a lateral extension extends, the lateral extension being configured for being clamped by an encapsulant tool pin during encapsulation, an electronic component mounted on the component mounting area, and an encapsulant encapsulating at least part of the electronic component and part of the carrier, wherein the lateral extension is laterally retracted with respect to a neighboring vertical sidewall of the encapsulant, and wherein the encapsulant laterally covers the lateral extension.

According to another exemplary embodiment, a method of manufacturing a package is provided, wherein the method comprises providing a carrier comprising a component mounting area from which a lateral extension extends, mounting an electronic component on the component mounting area, encapsulating at least part of the electronic component and part of the carrier by an encapsulant, wherein the lateral extension is clamped by an encapsulant tool pin during at least part of the encapsulating, and adjusting the encapsulating so that the lateral extension is laterally retracted with respect to a neighboring vertical sidewall of the encapsulant, and so that the encapsulant laterally covers the lateral extension.

According to an exemplary embodiment, an encapsulated (in particular molded) package is provided which has a carrier (which may be made for instance of a metallic material, in particular based on a leadframe structure) with a component mounting area (such as a die pad) carrying at least one electronic component (such as a semiconductor chip). At least one lateral extension may extend laterally from the component mounting area. The lateral extension may be used to be clamped down by an encapsulant tool pin during the process of encapsulating carrier and electronic component by an encapsulant (such as a mold compound). This clamping of the lateral extension together with the component mounting area of the carrier may prevent an undesired flow of still flowable encapsulant to the bottom side of the carrier which may allow to avoid undesired phenomena such as mold flash or bleeding of encapsulant material into unintentional regions of the package. Advantageously, the lateral extension may be laterally retracted with respect to a neighboring (in particular exterior or outermost) vertical sidewall (which may be defined by a sawing process) of the encapsulant. Consequently, a process of separating the package from other packages during a batch manufacturing process may be simplified, since no sawing through (in particular metallic material) of the lateral extension may be necessary. This may significantly accelerate and simplify the singulation process. When such a sawing process extends substantially only through encapsulant material (and optionally through one or more optional tiny tie pads), this may lead to a configuration in which the encapsulant laterally covers the lateral extension and therefore provides a sideways buffer between lateral extension and vertical sidewall of the package. As a result, undesired burrs may be reliably prevented at the package's sidewalls, which may be generated when sawing through the lateral extension. Due to the described package architecture, artefacts such as mold flash and/or burrs may be efficiently suppressed, while simultaneously allowing a simple and efficient manufacture of the package. As a result, packages may be provided which can be manufactured with high device reliability and in a simple and quick way.

### Description of Further Exemplary Embodiments

In the following, further exemplary embodiments of the package, and the method will be explained.

In the context of the present application, the term “package” may particularly denote an electronic device which may comprise one or more electronic components mounted on a carrier. Said constituents of the package may be encapsulated at least partially by an encapsulant. Optionally, one or more electrically conductive interconnect bodies (such as bond wires and/or clips) may be implemented in a package, for instance for electrically coupling the electronic component with the carrier and/or with leads.

In the context of the present application, the term “carrier” may particularly denote a support structure (which may be at least partially electrically conductive) which serves as a mechanical support for the one or more electronic components to be mounted thereon, and which may also contribute to the electric interconnection between the electronic component(s) and the periphery of the package. In other words, the carrier may fulfil a mechanical support function and an electric connection function. A carrier may comprise or consist of a single part, multiple parts joined via encapsulation or other package components, or a subassembly of carriers. When the carrier forms part of a leadframe, it may comprise a die pad.

In the context of the present application, the term “component mounting area” may particularly denote a section of the carrier which is configured for mounting at least one electronic component thereon. For instance, the component mounting area may be a die pad. In an embodiment, the component mounting area may be a planar plate-like metallic body or region.

In the context of the present application, the term “lateral extension” may particularly denote a portion of the carrier which may extend from a lateral side or edge of the component mounting area and may thus be a sideways protrusion of the component mounting area of the carrier. For example, the lateral extension may be integrally formed with the component mounting area and may extend as an appendix from the component mounting area. In an embodiment, the lateral extension may be a metallic plate or stripe section. The lateral extension may be co-planar with the component mounting area. The lateral extension may have a smaller length and width than the component mounting area. It is possible that a plurality of lateral extensions extend from different edge portions of the component mounting area, for instance from two opposing edge portions. The lateral extension may serve as a support or basis for an encapsulant tool pin clamping downwardly the lateral extension together with the connected component mounting area during forming an encapsulant. Descriptively speaking, it may be possible to denote the lateral extension as a mold ear in an exemplary embodiment. As the component mounting area, also the at least one lateral extension may be made of a metal, such as copper.

In the context of the present application, the term “clamping the lateral extension by an encapsulant tool pin” may particularly denote a process during which a retractable, liftable or removable encapsulant tool pin of an encapsulant tool (for instance a mold tool) may press the lateral extension of the carrier against a support surface (for instance of the encapsulant tool) during the encapsulation process to thereby clamp the lateral extension together with the component mounting area onto the support surface for preventing flow of encapsulant material to an opposing side of the carrier. This may suppress encapsulation artefacts, such as mold flash.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), a light emitting, semiconductor-based device (such as a light emitting diode (LED) or LASER), an actuator (for instance a loudspeaker), and a microelectromechanical system (MEMS). In particular, the electronic component may be a semiconductor chip having at least one integrated circuit element (such as a diode or a transistor) in a surface portion thereof. The electronic component may be a naked die or may be already packaged or encapsulated. Semiconductor chips implemented according to exemplary embodiments may be formed in silicon technology, gallium nitride technology, silicon carbide technology, etc.

In the context of the present application, the term “encapsulant” may particularly denote a substantially electrically insulating material surrounding at least part of an electronic component and at least part of a carrier to provide mechanical protection, electrical insulation, and optionally a contribution to heat removal during operation. In particular, said encapsulant may be a mold compound. A mold compound may comprise a matrix of flowable and hardenable material and filler particles embedded therein. For instance, filler particles may be used to adjust the properties of the mold component, in particular to enhance thermal conductivity.

In the context of the present application, the term “the lateral extension is laterally retracted with respect to a neighboring vertical sidewall of the encapsulant” may particularly denote the fact that a free lateral end of the lateral extension may remain laterally spaced with respect to a vertically extending sidewall portion of the encapsulant (and preferably also of the package as a whole) next to said lateral extension. The exterior end of the lateral extension may be shifted inwardly with respect to the juxtaposed exterior or outermost vertical sidewall of the encapsulant. In such a configuration, the lateral extension does not form part of the vertical sidewall of the package.

In the context of the present application, the term “the encapsulant laterally covers the lateral extension” may particularly denote that the lateral extension may be not completely exposed but may be coated by material of the encapsulant at least at its exterior lateral end. Thus, encapsulant material may function as a spacer between the (in particular exterior or outermost) vertical sidewall of the encapsulant and the lateral end of the lateral extension.

In an embodiment, the carrier comprises a further lateral extension extending from the component mounting area and configured for being clamped by a further encapsulant tool pin during encapsulation, wherein the further lateral extension is laterally retracted with respect to a neighboring further vertical sidewall of the encapsulant, and wherein the encapsulant laterally covers the further lateral extension. When providing a plurality of lateral extensions which can be clamped onto a counter surface by an encapsulation tool pin or the like during encapsulation, undesired tilting of the component mounting area of the carrier can be inhibited even more reliably or efficiently. The different lateral extensions may extend from different edges of the component mounting area for a more balanced pressing characteristics. The features described herein for the lateral extension may apply also to the further lateral extension.

In an embodiment, the lateral extension and the further lateral extension extend from opposing sides of the component mounting area and are laterally retracted with respect to opposing vertical sidewalls of the encapsulant. For example, the lateral extension and the further lateral extension may have the same shape and dimension for obtaining a symmetrical package architecture. When one or more tie bars are foreseen, the lateral extensions may extend from the same edges of the component mounting area as the assigned one or more tie bars. For instance, two of four side edges of a substantially rectangular component mounting area may be provided for forming lateral extensions (an optional tie bars), whereas the other two side edges may be provided for providing or connecting leads or lead sections. This may result in a compact design of the package.

In an embodiment, the encapsulant has a recess in the vertical sidewall extending vertically up to only one of two opposing main surfaces of the package. Such a recess may be the package's fingerprint of the temporary presence of one or more encapsulation tool pins during the manufacturing process, wherein such an encapsulation tool pin may be removed from the package during or at the end of the manufacturing process, leaving a corresponding recess behind. Such a recess in an edge of the package may have a closed bottom which may be delimited by a portion of the lateral extension and/or by a portion of the encapsulant.

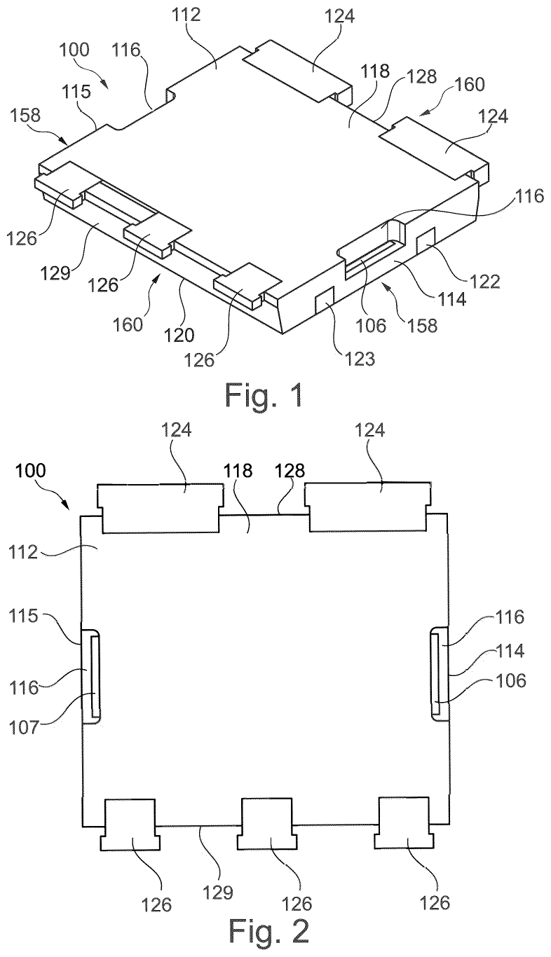

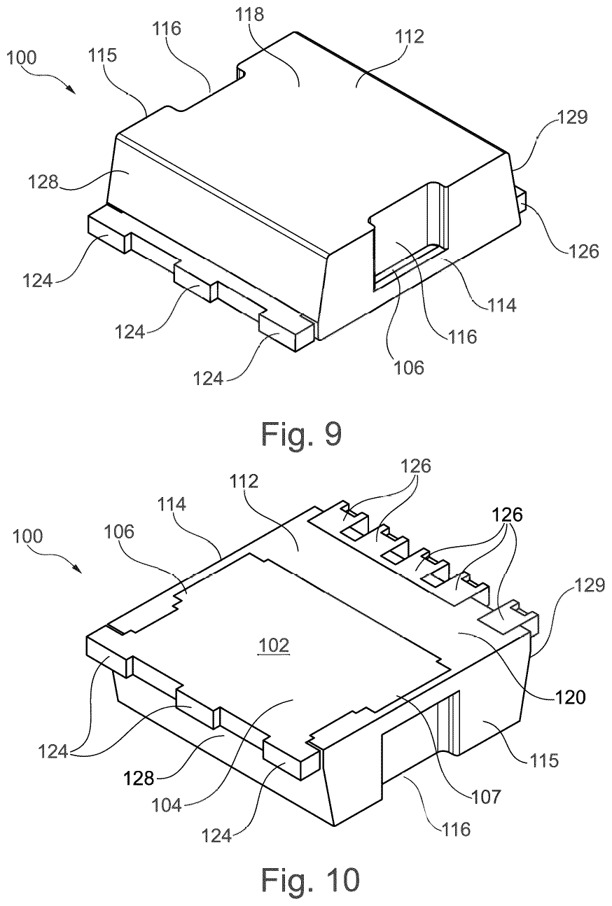

In an embodiment, the lateral extension is exposed in the recess. More specifically, the lateral extension may be exposed exclusively at a bottom of the recess. Correspondingly, the method may comprise clamping on the lateral extension by the encapsulant tool pin during an entire encapsulation process so that a recess is formed in the encapsulant in which recess the lateral extension is exposed. Such embodiments are shown for example in FIG. 1 or FIG. 9. A corresponding configuration may be obtained when an encapsulation tool pin clamps or presses onto the corresponding lateral extension until the encapsulation process is completed, for instance until a mold compound is cured. Removing the encapsulation tool pin afterwards may expose at least a portion of the lateral extension.

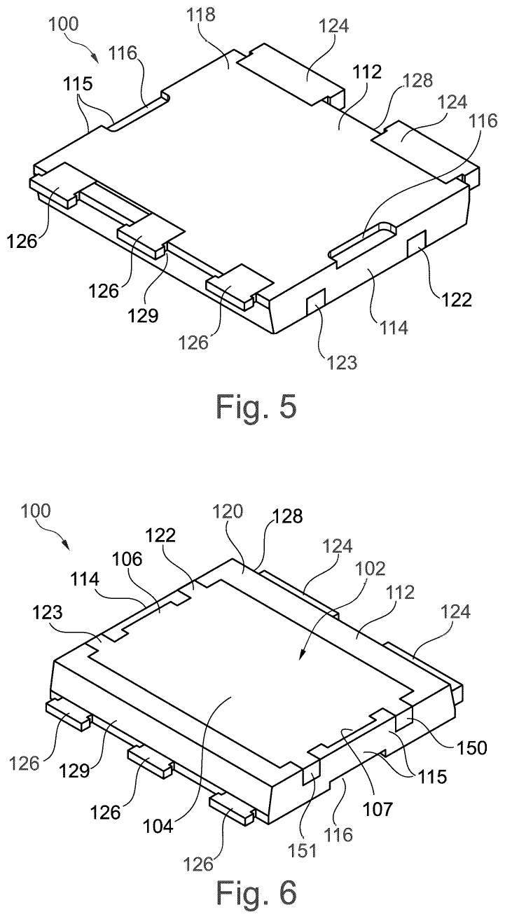

In another embodiment, the lateral extension is vertically separated from the recess by the encapsulant. Accordingly, the method may comprise clamping on the lateral extension by the encapsulant tool pin during a first part of an encapsulation process and retracting the encapsulant tool pin during a second part of the encapsulation process so that a recess is formed in the encapsulant with the lateral extension being vertically separated from the recess by the encapsulant. Such an embodiment is shown for instance in FIG. 5. The described configuration may be obtained when an encapsulation tool pin clamps or presses onto the corresponding lateral extension only at the beginning of the manufacturing process, whereas the encapsulation tool pin may be removed from the package before the encapsulation process is completed, for instance before a mold compound is fully cured. The temporarily exposed portion of the lateral extension may then be covered by still flowable encapsulant material, before the latter is fully cured. Removing the encapsulation tool pin before completing curing of the encapsulant may lead to a configuration in which the lateral extension beneath the recess is covered by encapsulant material at a bottom of the recess.

In an embodiment, the at least one vertical sidewall, which may be a sawn side flank of the package, is defined, in particular exclusively, by the encapsulant. In such an embodiment, sawing of said side flank(s) may be carried out exclusively through encapsulant material, in particular mold compound material. Since metal sawing may be completely avoided in such an embodiment, a high-speed sawing and thereby efficient processing can be ensured.

In another embodiment, the package comprises at least one tie bar extending from the component mounting area and being exposed at the vertical sidewall of the encapsulant. Thus, the at least one vertical sidewall, which may be a sawn side flank of the package, may be defined, in particular exclusively, by the encapsulant and a (in particular metallic) tie bar connected to the component mounting area of the carrier. Such a tie bar may be used for integrally connecting various carriers in a common carrier structure (such as a leadframe) prior to singulation into individual packages. In particular, a ratio between a surface area of an exposed tie bar at a respective sawn side flank and an entire surface area of the respective sawn side flank may be less than 10%, in particular less than 5%, more particularly less than 3%. In such an alternative embodiment, sawing is carried out through material of the (in particular mold-type) encapsulant in combination with only a very limited amount of material of the metallic tie bar(s). Said highly limited tie bar sawing may saw through only a few percent surface area of metal material which maintains the advantage of high-speed sawing substantially through encapsulant material. At the same time, said tie bar may connect different carriers of a leadframe and may thereby increase the mechanical stability during manufacture. As a consequence, highly accurate packages may be obtained.

In an embodiment, the lateral extension extends between two tie bars extending from the component mounting area. For example, the lateral extension may extend from a central side edge of the component mounting area and may be arranged between two tie bars. Advantageously, such a configuration may be formed on two opposing side edges of the component mounting area, i.e. for the lateral extension and for the above mentioned further lateral extension. This may lead to a symmetric design. With the described configurations of lateral extension(s) and tie bar(s), a high stability and positional accuracy may be achieved. While the tie bars may ensure an accurate mutual positioning and orientation between different carriers being interconnected by the tie bars, the lateral extensions may avoid encapsulant flow to the bottom side of the carriers while inhibiting burrs at the vertical sidewalls of the packages.

In an embodiment, the lateral extension has a smaller length than and/or a larger width than and/or the same thickness as the at least one tie bar. In this context, the length of a lateral extension or a tie bar may be its dimension from the component mounting area up to a free end. Furthermore, the width of a lateral extension or a tie bar may be its dimension along a corresponding side edge of the component mounting area from which it extends. Beyond this, the thickness of a lateral extension or a tie bar may be its dimension along a stacking direction of component mounting area and electronic component. When the length of the lateral extension is smaller than the length of the tie bar, it can be reliably ensured that the lateral extension does not extend up to the vertical sidewalls of the package, whereas the tie bar does. For instance, the length of the lateral extension may be not more than half, preferably not more than one third, of the length of the tie bar. When the width of the lateral extension is larger than the width of the tie bar, it can be reliably ensured that the lateral extension can be clamped downwardly efficiently by an encapsulant tool pin, while the tie bar is sufficiently narrow for avoiding burrs where the tie bar crosses the vertical sidewalls of the package. For instance, the width of the lateral extension may be at least twice, preferably at least three times, of the width of the tie bar. When the thickness of the lateral extension and the tie bar is the same, and is preferably the same as the thickness of the component mounting area, the entire carrier can be formed based on a metal plate (which may for instance be patterned and/or bent).

In another embodiment, the package is configured as tie bar-less package. Such a configuration shown in FIGS. 9 to 12. Hence, the package may be entirely free of tie bars. This may have the advantage that sawing the vertical sidewalls may involve only sawing through encapsulant material (in particular mold compound) so that no sawing through metal is necessary in such an embodiment. Singulation along the long leadframe axis may then be designed so as to permit fast saw singulation (in particular without a metal, such as copper, in the saw streets).

In an embodiment, the vertical sidewall is formed exclusively by the encapsulant, or exclusively by the encapsulant and at least one tie bar. When retracting the one or more lateral extensions with respect to the vertical sidewalls and keeping them inside of the encapsulant outline of the package a quick and simple singulation is possible, while an efficient inhibition of burrs at the vertical sidewalls may be achieved.

In an embodiment, the package comprises one or more electrically conductive lead sections, in particular at least one of which being integrally formed with the component mounting area and/or at least one of which being formed separately from the component mounting area, extending out of the encapsulant at one or two slanted sidewalls of the encapsulant. Each lead section may comprise one or more leads. At least one lead section may be integrally formed with the component mounting area, the lateral extension(s) and the optional tie bar(s). Additionally or alternatively, at least one lead section may be formed as a separate body with respect to the component mounting area, the lateral extension(s) and the optional tie bar(s), and may be electrically coupled with the component mounting area and/or at least one electronic component mounted thereon by one or more electrically conductive connection structures (such as bond wires and/or clips). For example, lead sections may be arranged along edges of the component mounting area at which no lateral extensions and/or tie bars are present. In the context of the present application, the term “lead” may in particular denote an electrically conductive (for instance strip shaped) element (which may be planar or bent) which may be assigned functionally to the carrier and which serves for contacting the electronic component with an exterior of the package. For instance, a lead may be partially encapsulated and partially exposed with respect to an encapsulant. When the carrier forms part of a leadframe, leads may surround a die pad of the carrier, for instance at two opposing sides. The one or more leads may or may not form part of the carrier.

In an embodiment, said one or two slanted sidewalls may have a molded texture. Correspondingly, the method may comprise forming a slanted sidewall of the encapsulant by a slanted sidewall of an encapsulant tool cavity. This may lead to a molded texture. In the context of the present application, the term “molded texture” may particularly denote a characteristic surface profile of a side flank formed by molding. In particular, such a molded texture may comprise a smooth surface (in particular having a lower surface roughness Ra than a side flank with a sawn texture) with microscopic surface pixels corresponding to filler particles added to a mold compound, appearing at an exterior surface of a mold-type encapsulant and being coated with molded encapsulant material (in particular mold resin).

In an embodiment, the vertical sidewall has a sawn texture. Correspondingly, the method may comprise forming the vertical sidewall of the encapsulant by mechanically sawing. In the context of the present application, the term “sawn texture of side flanks or vertical sidewalls” may particularly denote a surface structure or surface profile on a side surface of an encapsulant being defined by sawing. Preferably, said sawing process is a mechanical sawing process using a saw blade. Alternatively, also laser sawing is possible. Due to such a sawing process, in particular mechanical sawing process using a saw blade, a rough surface texture (in particular having a roughness Ra of more than 0.8 μm, in particular between 0.8 μm and 5 μm, for instance around 1 μm) is obtained. Such a saw rough characteristic of a sawn side flank is combined with the formation of microscopic scratches, marks, rills or corrugations formed by the sawing tool. For instance, a mechanical saw blade may have polyimide bound diamond bodies used for sawing which may for example create the mentioned sawn texture. In particular, a sawn texture of the at least one side flank may comprise a roughness Ra of more than 0.8 μm in combination with corrugations having larger dimensions compared to dimensions of protrusions and indentations relating to a said roughness. The roughness of a surface may be defined as and may be measured as the centerline average height Ra. Ra is the arithmetic mean value of all distances of the profile from the centerline. For instance, the measurement or determination of roughness Ra of the sawn surface, as mentioned in the context of the present application, may be carried out according to DIN EN ISO 4287:2010. A saw used for forming the sawn texture may be denoted as a tool comprising a tough saw blade with a hard-toothed edge. Such a saw may be used to cut through encapsulant material and optionally also through metallic material of the one or more leads by placing the tooth edge against the material and moving it forcefully forth and less forcefully back or continuously forward. For instance, a powered circular saw blade may be used for this purpose. At a sawn side flank of an encapsulant, in particular a sawn side flank of a mold compound, a broken surface may be obtained at which also filler particles are sawn at the surface of the sawn side flank. As a consequence, a sawn side flank may be defined by material of the above-described matrix of the encapsulant and partially also by cut non-coated filler particles.

In an embodiment, a main surface of the component mounting area facing away from the electronic component is exposed with respect to the encapsulant. Such an exposed main surface of the carrier's component mounting area may allow to efficiently remove heat generated by the at least one electronic component during operation of the package. Since the carrier may be made partially or entirely form a metallic material which may also have a high thermal conductivity, heat removal by an exposed carrier surface may be much more efficient than through material of the encapsulant, having usually a significantly lower thermal conductivity than the carrier. When the carrier is exposed with respect to the encapsulant at one main surface of the package, exposed electrically conductive surfaces may be provided which may simplify electrically connecting the package and which may also promote heat dissipation during operation of the package (in particular when the electronic component is a power semiconductor chip).

In an embodiment, the method comprises providing an oblong carrier structure comprising the carrier and at least one additional carrier comprising at least one additional component mounting area from which at least one additional lateral extension extends, mounting at least one additional electronic component on the at least one additional component mounting area, encapsulating at least part of the at least one additional electronic component and part of the at least one additional carrier by an oblong encapsulant structure to which also said encapsulant belongs, wherein the at least one additional lateral extension is clamped by at least one additional tool pin and/or by said encapsulant tool pin during at least part of the encapsulating (one option is that the clamping of two neighboring mold ears can be done by only one pin), and separating an obtained structure into individual packages each comprising a respective one of said carriers, a respective one of said electronic components, and a part of said encapsulant structure as a respective encapsulant, so that each of the lateral extensions is laterally retracted with respect to a neighboring vertical sidewall of a respective one of the encapsulants, and so that each respective of the encapsulants laterally covers the respective lateral extension.

Still referring to the previously described embodiment, the method may comprise mounting additional electronic components on additional (preferably electrically conductive) carriers (which may be designed as the carrier described above, in particular with one or more lateral extensions), so that the electronic components and the carriers are arranged in a plurality of rows and columns, encapsulating at least part of the additional carriers and the additional electronic components by additional encapsulant, and sawing vertical sidewalls or side flanks of the encapsulant structure(s) to form separate encapsulants. It may also be possible to provide additional leads or lead sections and to punch leads or lead sections extending beyond the encapsulants. Thus, the manufacturing method may be carried out on leadframe or panel level, i.e. for multiple carriers and for multiple electronic components simultaneously. Such a batch process further reduces the manufacturing effort and allows manufacturing packages on an industrial scale. The carriers and consequently the packages may be arranged in a matrix-like way in rows and columns. Descriptively speaking, sawing may be carried out horizontally, i.e. along the rows, whereas punching may be carried out vertically, i.e. along the columns. In this way, a highly efficient manufacturing process may be obtained.

In particular, the method may comprise forming a plurality of parallel encapsulant structures or bars of material of the encapsulant and the additional encapsulant, wherein each encapsulant structure or bar at least partially encapsulates all carriers and all electronic components of a respective column. According to such a preferred embodiment, encapsulant structures or bars may be formed covering for instance all carriers and electronic components of a column of the matrix-like arrangement of preforms of packages simultaneously. As a result, an arrangement of parallel vertically extending encapsulant bars or structures may be obtained. This may be carried out highly advantageously by molding. In particular, the combination of the formation of vertically extending encapsulant bars with the horizontal extension of the leads or lead sections may be of utmost advantage.

In an embodiment, the method comprises sawing each of the encapsulant structures or bars to thereby separate a plurality of packages. Hence, each encapsulant structure or bar may be cut into a plurality of individual portions, each portion being assigned to a respective package. This cutting may be accomplished by sawing, in particular mechanically sawing. However, also sawing the multiple encapsulant structures or bars may be carried out in a common process in which a saw blade may saw all parallel and spaced encapsulant structures or bars by firstly sawing along a first horizontal saw row, followed by a second horizontal saw row, and so on.

In an embodiment, the method comprises connecting the carrier with the at least one additional carrier by at least one tie bar, and separating the obtained structure into the individual packages by sawing through the encapsulant structure and through the at least one tie bar. For instance, the method may comprise connecting carriers of at least one column with at least one tie bar. It is also optionally possible to subsequently separate the obtained structure into the plurality of packages by sawing through the at least one tie bar. These tie bars may improve the stability of the leadframe and of the structures obtained during manufacturing packages. Advantageously, the cross-section of the tiny tie bars may be kept very small so that the sawing process cuts mostly through encapsulant material with only a very small content of metallic material.

In an embodiment, the method comprises punching lead sections extending beyond the encapsulant and being electrically coupled with the carrier and/or the electronic component. Said punching may lead to a punched surface. In the context of the present application, the term “punched surface” may particularly denote a surface area delimiting the one or more leads and being defined by punching. Punching may denote a forming process that uses a punch press to force a tool, which may be denoted as a punch, through the workpiece to create a hole via shearing. Punching is applicable to a wide variety of materials in sheet form, including sheet metal. Punching is a simple and therefore highly efficient method of defining structures in a patterned sheet material. Correspondingly, a punched surface is a surface defined by punching. A person skilled in the art will understand that a punched surface has dedicated properties which can be easily and unambiguously analysed by a person skilled in the art. At the punched surface delimiting the lead, a corresponding side flank of the encapsulant may be defined by the encapsulation process, in particular by molding. A corresponding encapsulant, such as a mold compound, may comprise a matrix (for instance comprising a resin) with filler particles. At a molded surface corresponding to a punched surface of the leads, the filler particles are coated by matrix material of the in particular mold compound-type encapsulant so as to form a defined structure with coated pixels on the surface. Moreover, a molded side flank at a punched surface of a corresponding lead may be slanted (for instance with a slanting angle in a range between 6° and 12°, in particular between 8° and) 10° for promoting removal of a corresponding mold body out of a mold tool.

In an embodiment, the method comprises carrying out the punching before the sawing. Thus, the above-mentioned encapsulant structure(s) or bar(s) may still remain intact and provide their stabilization after punching. At the very end, they may be sawn by a mechanical saw blade into the individual packages.

In an embodiment, the method comprises clamping on the lateral extension by the encapsulant tool pin during encapsulation so that the component mounting area is pressed onto a counter surface of an encapsulation tool. This may prevent the carrier from tilting during the encapsulation process so that an unintentional flow of encapsulant to the back side of the carrier may be reliably prevented. Hence, undesired phenomena such as mold flash or bleeding may be inhibited.

In an embodiment, a leadframe may be used as carrier structure. In the context of the present application, the term “leadframe” may particularly denote a metal structure comprising an array of initially integrally connected carriers and leads for packages. The electronic components may be attached to the carriers of the leadframe, and then bond wires and/or clips may be provided for attaching pads of the electronic component to leads of the leadframe. Subsequently, the leadframe may be molded in a plastic case or any other encapsulant. Outside and/or inside of the leadframe, corresponding portions of the leadframe may be cut-off, thereby separating the respective leads and/or carriers. A leadframe may be composed of multiple carriers for electronic components, wherein each carrier may have a component mounting area, at least one lateral extension, optionally tie bars, and one or more leads or lead sections.

In an embodiment, the above-mentioned leadframe may comprise at least one tie bar extending along the columns and connecting carriers of at least one column. Tie bars on leadframe level are highly advantageous for keeping together the individual carriers of the leadframe before separation thereof. In particular before encapsulation, said individual carriers may be difficult to handle in the absence of connecting structures such as tie bars.

In an embodiment, the electronic component is configured as a power semiconductor chip. Thus, the electronic component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide or gallium nitride). A semiconductor power chip may comprise one or more field effect transistors, diodes, inverter circuits, half-bridges, full-bridges, drivers, logic circuits, further devices, etc.

As substrate or wafer forming the basis of the electronic components, a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in gallium nitride or silicon carbide technology.

For the encapsulating, a plastic-like material or a ceramic material which may be subsidized by encapsulant additives such as filler particles, additional resins or others may be used.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

A recently developed manufacturing architecture for packages involves the formation of common encapsulant structures for a plurality of packages and the subsequent separation by sawing through encapsulant and metallic carrier structures as well as punching through lead structures. A corresponding molding process may be supported with mold pins holding tie bars during molding and includes the above mentioned sawing process as the final singulation.

However, since a cavity is formed by the mold pins over the tie bars, during sawing, burrs from the tie bars may be stuck in these spaces. This may lead to packages with pronounced burrs which may be beyond an acceptable burr specification.

According to an exemplary embodiment, a package having an exterior outline being delimited partially by an encapsulant comprises a carrier (preferably being at least partially electrically conductive) which may delimit another portion of the exterior outline of the package. Such a carrier may have a component mounting area, such as a die pad, on which one or more electronic components (for example one or more semiconductor dies) are mounted. Advantageously, one or more lateral extension may extend sideways (for example horizontally) from the component mounting area. The lateral extension may serve for clamping it down onto a counter surface by at least one encapsulant tool pin while a flowable encapsulant is supplied for encapsulating part of the carrier and at least part of the electronic component, for example during molding. Clamping the lateral extension and with it the component mounting area onto a surface may suppress or eliminate an unintentional flow of not yet hardened encapsulant beneath the carrier. Advantageously, this may reliably prevent artefacts like mold flash. Beneficially, the lateral extension can be displaced sideways relative to an adjacent planar and preferably vertical sidewall of the encapsulant which may be defined by sawing during a singulation process at the end of a batch manufacture. This may render the manufacturing process fast, because sawing through metal of the lateral extension may be dispensable. A reliable, fast and easy manufacture may be combined which may lead to a high yield and a manufacturability of packages on an industrial scale. Since a sawing process for singulation may extend at least predominantly or even entirely through encapsulant material, a package may be obtained in which the encapsulant is located sideways on the lateral extension. This may allow to avoid unintentional burrs of exposed carrier material which may be created unintentionally when sawing through a metal. By the package design and a corresponding manufacturing concept as described, undesired phenomena as mold flash, burrs or the like can be inhibited or even eliminated. At the same time, it may be possible to produce the packages in a quick and easy way. Thus, a package according to an exemplary embodiment may combine excellent device reliability with a simple manufacturing process.

To put it shortly, an integration of lateral extensions (which may also be denoted as mold ear integration) in a package (for instance with tie bar-support or in a tie bar-less configuration) may be accomplished in such a way that said lateral extensions remain partially covered by encapsulant (in particular molded) material at a lateral end and remain spatially separated form vertical sidewalls of the package. This avoids sawing through the preferably metallic lateral extensions during singulation to thereby prevent burrs, while simultaneously benefiting from the lateral extensions which can be pressed down by encapsulation tool pins to avoid encapsulation flow towards a bottom side of the package.

For example, units of carriers and electronic components arranged in rows and columns in a manufacturing concept involving common encapsulant structures along columns may be provided with tie bars connecting the units in the frame structure, or in a tie bar-less fashion. Each unit may have one or more lateral extensions (which may be denoted as mold ears) which may extend from the component mounting area (which may be denoted as die pad) for mold clamping. Advantageously, said one or more lateral extensions may be arranged in the package so that they do not reach the neighboring exterior side end (which may be a vertical sidewall) of the package after saw singulation for saw burr elimination. In an exemplary embodiment, it may be possible to maintain for the full tie bars aids a good planarity of the die pad which may lead to a controlled total stack height.

During molding, in particular a large die pad-type component mounting area of the carrier may need to be held to avoid tilt which may otherwise lead to mold flash or bleed. The addition of one or more lateral extensions (which may be denoted as mold ears) for pin hold may mitigate this mold risk, while at the same time eliminating the occurrence of sawing burrs. Advantageously, such a manufacturing architecture can be applied to very different package types.

Beneficially, a manufacturing concept including common encapsulant bars each formed for a linear array of carriers and electronic components in common may be an enabler for high density in a frame leading to a reduction of the effort for producing packages. Advantageously, exemplary embodiments may eliminate sawing burr risks. This may be particularly useful for all packages, and especially for big packages. A corresponding package may have a vertical sidewall on the sides sawn at the lateral extension (and optionally tie bar) sides, with only the encapsulant (and optionally the tie bars) being sawn, so that the one or more lateral extensions do not reach the sidewall of the package. This may lead to the absence of lateral extension burrs at the vertical sidewalls of the package, with the one or more lateral extensions being partially or entirely covered by encapsulant material. Descriptively speaking, at least one mold ear feature at the sawn side of a package assembled through a multiple-package encapsulant bar concept may be spatially displaced from the sawn sidewalls of the package to avoid a cumbersome sawing through metallic lateral extensions.

More specifically, package units may be arranged in ultrahigh density fashion with common bar-shaped encapsulant structures with optional tie bars connecting the units in the frame. Each unit may have extensions from the die pad (which may be called mold ears) for mold clamping which do not reach the effective side of the package after saw singulation for saw burr elimination. With such an approach, a sawing blade used for singulation may only run through the mold compound along the kerf (and the optional tie bar(s), if present) and will not touch or disturb the mold ear(s), so that sawing burrs will not occur.

Corresponding packages may be sawn through the encapsulant at the (optional) tie bar and mold ear sides, with only the encapsulant (and the tie bars, if present) being sawn with the mold and the mold ears or lateral extensions not reaching the side edge of the package. The two sides of the package (which may be denoted as tie bar sides, if tie bars are present) may be preferably separated via a mechanical sawing process, rather than by punching.

In an embodiment, a method to integrate mold ears or lateral extensions in a (for instance tie bar-supported) package may be provided. In such a method, a portion of a (preferably metallic) carrier, which may be denoted as lateral extensions or mold ears, may extend slightly outside from a die pad of the carrier but do not reach all the way to the effective sides of the package, thereby eliminating saw burrs caused due to saw singulation in a comparative scenario with lateral extensions extending up to the vertical sidewalls of the package. Advantageously, the lateral extensions may be used by encapsulant tool pins (such as mold pins or clamps) for holding onto the lateral extensions during the encapsulation (preferably molding) process, wherein the encapsulant tool pins hold the lateral extensions (and optionally also tie bars). Beneficially, the short length of the lateral extensions eliminate the likelihood of saw burrs as the lateral extensions do not come in contact with the saw during saw singulation of the package. Tie bars may aid in maintaining planarity of the die pad leading to controlled height of the total stack. Additionally, the assembly of a (for instance clip) package enables high density in a leadframe leading to a low manufacturing effort. In an embodiment, the addition of lateral extensions for pins to hold the die pad may be beneficial, since the die pad-type component mounting area may need to be stabilized to avoid encapsulant (in particular mold) flash or bleed resulting from tilting. Furthermore, this may eliminate the formation of burrs as well during sawing.

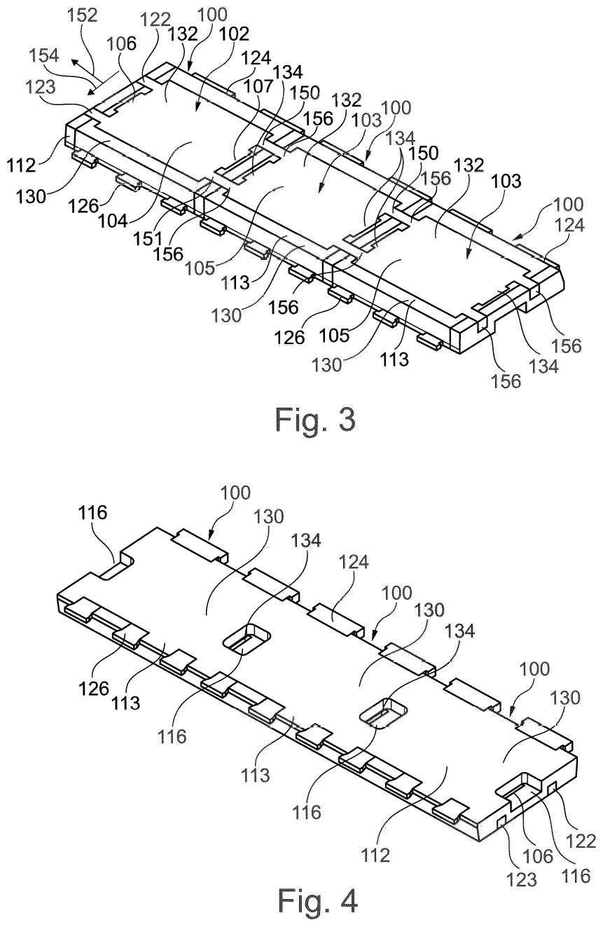

FIG. 1 illustrates a three-dimensional view of a package 100 according to an exemplary embodiment. FIG. 2 illustrates a plan view of the package 100 according to FIG. 1. Both FIG. 1 and FIG. 2 show predominantly the same side of the package 100. FIG. 3 and FIG. 4 show additional features.

The package 100 according to FIG. 1 and FIG. 2 comprises a carrier 102, which may comprise or consist of a metal such as copper. For instance, said carrier 102 may be embodied as a leadframe structure. Since a major portion of the carrier 102 is encapsulated by an encapsulant 112 (such as a mold compound), said major portion of the carrier 102 is not visible in FIG. 1 and FIG. 2. The construction of the carrier 102 of the package 100 of FIG. 1 and FIG. 2 can however be better seen in FIG. 3 showing a preform from which the package 100 of FIG. 1 and FIG. 2 has been singulated. The carrier 102 comprises a component mounting area 104 which may be embodied as a die pad.

From a lateral side edge of the component mounting area 104, a lateral extension 106 extends, which may also be denoted as a mold ear. The lateral extension 106 may be configured for being clamped down by an encapsulant tool pin (see reference sign 108 in FIG. 18) during the process of encapsulation, i.e. during forming the encapsulant 112. This may prevent undesired mold flash or mold bleed at the side of the package 100 at which the component mounting area 104 is exposed (see FIG. 3). As a consequence and as a fingerprint of this manufacturing process, the encapsulant 112 has a blind hole-type edge recess 116 in the vertical sidewall 114 extending up to only one main surface 118 of two opposing main surfaces 118, 120 of the package 100. The recess 116 is arranged where the encapsulant tool pin 108 had been present during the encapsulation process. Said recess 116 is shaped as a notch extending sidewise and vertically into the encapsulant 112 to thereby expose a portion of the lateral extension 106. Thus, the encapsulant 112 has the recess 116 in the vertical sidewall 114 extending up to only one of two opposing main surfaces 118, 120 of the package 100 so that the lateral extension 106 is exposed in the recess 116. The recess 116 is partially delimited by the lateral extension 106 and partially delimited by the encapsulant 112. Thus, the lateral extension 106 is exposed in the recess 116. A horizontal bottom surface delimiting the recess 116 has an exterior encapsulant section next to vertical sidewall 114 and has an interior metallic section defined by the lateral extension 106. Vertical surface sections delimiting the recess 116 are defined by the encapsulant 112 only.

In a way as shown for instance in FIG. 14, an electronic component 110 may be mounted on the encapsulated surface of the component mounting area 104. For instance, the electronic component 110 may be a semiconductor die, such as a power semiconductor die. The electronic component 110 may be assembled on the component mounting area 104 by an electrically conductive connection medium, such as a solder, a sinter material and/or electrically conductive glue. It is also possible that a plurality of electronic components are mounted on the component mounting area 104.

The already mentioned encapsulant 112 may encapsulate the electronic component 110 entirely and the carrier 102 partially.

Now referring again to FIG. 1 and FIG. 2, the lateral extension 106 is laterally retracted with respect to neighboring outermost vertical sidewall 114 of the encapsulant 112. Thus, the lateral extension 106 extends towards, but does not extend up to the spatially closest vertical sidewall 114 defined at least predominantly by the encapsulant 112. As shown in FIG. 1 in FIG. 2, the encapsulant 112 laterally covers the lateral extension 106 so that the encapsulant 112 extends up to the vertical sidewall 114, whereas the lateral extension 106 remains spaced with respect to the vertical sidewall 114. When separating the package 100 from a larger compound, the lateral spacing between the lateral extension 106 and the vertical sidewall 114 of the package 100 has the advantage that a mechanical sawing blade saws predominantly through the encapsulant 112 for forming the vertical sidewall 114, but does not have to cut through the metallic lateral extension 106. This accelerates and simplifies the sawing process while preventing burrs at the lateral extension 106 which may result from metal cutting.

As can be seen best in FIG. 2 and FIG. 3, the carrier 102 comprises a further lateral extension 107 extending from another side edge of the component mounting area 104 and configured for being clamped by a further encapsulant tool pin (see reference sign 109 in FIG. 18, or even by the same encapsulant tool pin 108) during encapsulation. The further lateral extension 107 and a corresponding further recess 116 being partially delimited by said further lateral extension 107 may be constructed as the above-described lateral extension 106 partially delimiting the afore-mentioned recess 116 (see FIG. 2). More specifically, said further lateral extension 107 is laterally retracted with respect to a neighboring further outermost vertical sidewall 115 of the encapsulant 112. Moreover, the encapsulant 112 laterally covers also the further lateral extension 107. As shown in FIG. 2 and FIG. 3, the lateral extension 106 and the further lateral extension 107 extend from opposing sides of the component mounting area 104 and are laterally retracted with respect to opposing vertical sidewalls 114, 115 of the encapsulant 112. Thus, the lateral extensions 106, 107 extend from opposing sides edges of the component mounting area 104 and are partially exposed in bottom walls of blind hole-type recesses 116, 116 formed in opposing vertical sidewalls 114, 115 of the encapsulant 112 and the package 100 as a whole.

Now referring to FIG. 1 and additionally to FIG. 3 and FIG. 4, package 100 comprises tie bars 122, 123 extending from the component mounting area 104 and being exposed at the vertical sidewall 114 of the encapsulant 112. As shown, the lateral extension 106 extends between the two tie bars 122, 123 extending from the same side edge of the component mounting area 104 from which also the lateral extension 106 extends. Correspondingly, package 100 comprises further tie bars 150, 151 (see FIG. 3) extending from an opposing side edge of the component mounting area 104 from which also the further lateral extension 107 extends and being exposed at the opposing vertical sidewall 115 of the encapsulant 112. The further lateral extension 107 extends between the two further tie bars 150, 151 extending from the component mounting area 104.

As best seen in FIG. 3, each of the lateral extensions 106, 107 has a smaller length in a longitudinal length direction 152 extending from the respectively assigned side edge of the component mounting area 104 up to the free end of the respective lateral extension 106, 107 than the tie bars 122, 123, 150, 151. Moreover, each of the lateral extensions 106, 107 may have a larger width in a transversal width direction 154 perpendicular to the longitudinal length direction 152 and within the plane defined by the component mounting area 104 and the tie bars 122, 123, 150, 151. The thickness of the lateral extensions 106, 107 may be the same as the thickness of the tie bars 122, 123, 150, 151 and/or as the thickness of the component mounting area 104. For example, the lateral extensions 106, 107, the tie bars 122, 123, 150, 151 and the component mounting area 104 may be formed based on a common metal sheet, which may be patterned and/or bent.

As best seen in FIG. 1, the vertical sidewall 114 is formed exclusively by the encapsulant 112 and the tie bars 122, 123. Correspondingly, the vertical sidewall 115 is formed exclusively by the encapsulant 112 and the tie bars 150, 151. In contrast to this, the lateral extensions 106, 107 do not form part of the vertical sidewalls 114, 115. When sawing a larger encapsulant structure for separating the package 100, the mechanical sawing blades saw substantially through mold compound only, and through the tiny tie bars 122, 123, 150, 151. No sawing through the spatially retracted lateral extensions 106, 107 is necessary, so that the risk of burr formation due to the lateral extensions 106, 107 can be eliminated. To put it shortly, a respective mold ear (in form of lateral extensions 106, 107) on each sawn side (i.e. at vertical sidewalls 114, 115) of the package 100 may be provided without any copper burrs. The extended die paddle-type component mounting area 104 with its mold ear-type lateral extensions 106, 107 may be configured so that the lateral extensions 106, 107 do not reach the sides of the package 100. Thus, the lateral extensions 106, 107 extending sidewise from the die pad-type component mounting area 104 may serve for mold clamping, but do not reach the effective side of the package 100 after saw singulation for saw burr elimination.

The package 100 additionally comprises electrically conductive (preferably metallic, for instance made of copper) lead sections 124, 126 extending partially within and partially outside of the encapsulant 112. Lead section 124 may be integrally formed with the component mounting area 104. Lead section 126 may be a body being separate from the component mounting area 104, but may be electrically coupled with the electronic component 110 and/or with the component mounting area 104 by one or more electrically conductive connection elements (such as clips and/or bond wires, not shown). Both lead sections 124, 126 extend out of the encapsulant 112 at two opposing slanted sidewalls 128, 129 of the encapsulant 112. The slanted sidewalls 128, 129 may be defined by a profile of a cavity of an encapsulation tool used for encapsulating package 100, i.e. used for forming encapsulant 112 (preferably by molding). Consequently, the surfaces of the two slanted sidewalls 128, 129 may have a molded texture being the fingerprint of the molding process executed for defining the slanted sidewalls 128, 129. In contrast to this, the surfaces of the vertical sidewalls 114, 115 are formed by sawing and therefore have a sawn texture. By inspecting the respective texture, a skilled person may distinguish between a sawn texture and a molded texture.

As best seen in FIG. 3, the substantially rectangular component mounting area 104 of the carrier 102 has two opposing side edges from which the lateral extensions 106, 107 and the tie bars 122, 123, 150, 151 extend. The lead sections 124, 126 are arranged at the two remaining side edges of the component mounting area 104 and oppose each other.

Although not shown in FIG. 1 and FIG. 2, FIG. 3 illustrates that a main surface of the component mounting area 104 facing away from the encapsulated electronic component 110 is exposed with respect to the encapsulant 112. Thus, heat dissipation from the encapsulated electronic component 110 can occur efficiently via the exposed highly thermally conductive surface of the component mounting area 104.

The two opposing main surfaces 118, 120 of the package may be parallel to each other. The vertical sidewalls 114, 115 may extend perpendicular to the main surfaces 118, 120. The slanted sidewalls 128, 129 may be slanted with respect to the vertical sidewalls 114, 115 and with respect to the main surfaces 118, 120. For instance, a slanting angle of the slanted sidewalls 128, 129 with respect to the vertical sidewalls 114, 115 may be in a range from 6° to 12°.

FIG. 3 illustrates a three-dimensional front view of a structure obtained during manufacturing a package 100 according to FIG. 1 and FIG. 2. FIG. 4 illustrates a three-dimensional back view of a structure obtained during manufacturing a package 100 according to FIG. 1 and FIG. 2.

For manufacturing the package 100, the carrier 102 may be provided having component mounting area 104 from which lateral extensions 106, 107 extend. An electronic component 110 may be mounted on one of two opposing main surfaces of the component mounting area 104. Thereafter, the electronic component 110 and part of the carrier 102 may be encapsulated by mold-type encapsulant 112. During encapsulation, the lateral extensions 106, 107 may be clamped by encapsulant tool pins 108, 109. The encapsulating process may be adjusted so that the lateral extensions 106, 107 are laterally retracted with respect to a respectively neighboring vertical sidewall 114, 115 of the encapsulant 112. Furthermore, the encapsulation process may be configured so that the encapsulant 112 laterally covers the lateral extensions 106, 107.

Now referring to a batch manufacturing process using the structures according to FIG. 3 and FIG. 4, it may be possible to provide an integrally formed oblong carrier structure 132 comprising the carrier 102 and additional carriers 103. Each of the additional carriers 103 may comprise an additional component mounting area 105 from which two additional opposing lateral extensions 134 extend. For each of the additional carriers 103, additional tie bars 156 may be provided as well, which may have corresponding properties as the above-described tie bars 122, 123, 150, 151. As shown, the carrier 102 and the additional carriers 103 are connected with each other by tie bars 122, 123, 150, 151, 156.

Moreover, additional electronic components 111 may be mounted on the additional component mounting areas 105, more precisely one or more electronic components 111 per additional component mounting area 105.

Thereafter, the additional electronic components 111 and part of the additional carriers 103 may be encapsulated, together with electronic component 110 and carrier 102, by an integrally formed oblong encapsulant structure 130 which may be shaped as a bar. Also the above-mentioned encapsulant 112 of package 100 belongs to said bar-shaped oblong encapsulant structure 130. The additional lateral extensions 134, as described above for lateral extensions 106, 107, are clamped by additional tool pins (see reference sign 136 in FIG. 18) and/or by the same encapsulant tool pins 108, 109 clamping lateral extensions 106, 107, 134 during the encapsulating process. At the end of the encapsulating process, the encapsulant tool pins 108, 109, 136 may be retracted or removed to thereby form recesses 116. As a result, the multi-package structure shown in FIG. 3 and FIG. 4 is obtained. More specifically, the manufacturing method may comprise clamping on the lateral extensions 106, 107, 134 by the encapsulant tool pins 108, 109, 136 during encapsulation so that the respective component mounting area 104, 105 is pressed onto a counter surface of an encapsulation tool for avoiding mold flash. In the embodiment of FIG. 1 to FIG. 4, clamping on the lateral extensions 106, 107, 134 by the encapsulant tool pins 108, 109, 136 may occur during an entire encapsulation process until curing of the encapsulant structure 130 is completed, so that the recesses 116 are formed in the encapsulants 112, 113, wherein the lateral extensions 106, 107, 134 are exposed in said recesses 116. At the end of the encapsulation process, the encapsulant tool pins 108, 109, 136 may be removed.

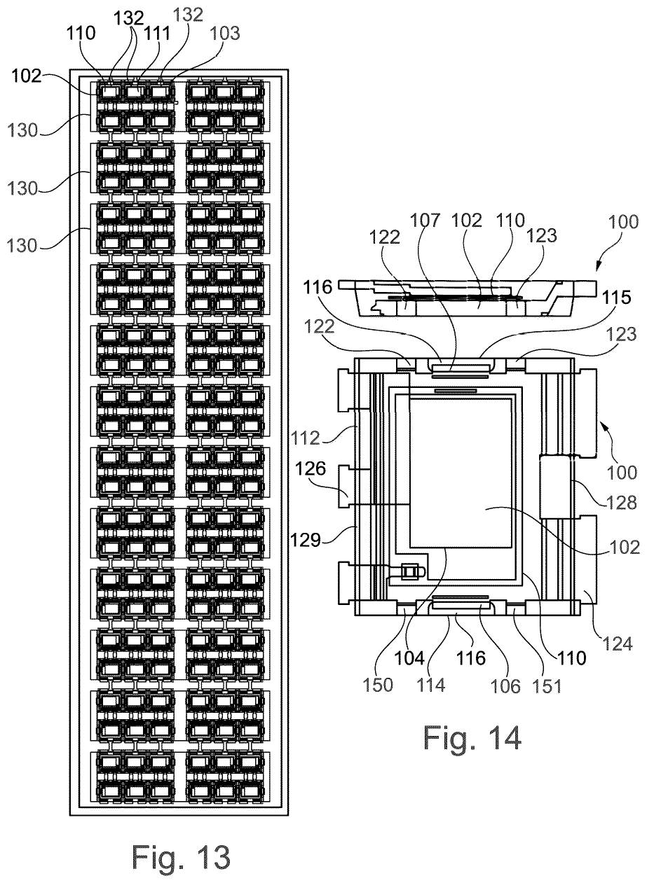

Thereafter, the obtained multi-package structure is separated into individual packages 100 each comprising a respective one of said carriers 102, 103, a respective one of said electronic components 110, 111, and a part of said encapsulant structure 130 as a respective encapsulant 112, 113. In the obtained individual packages 100, each of the lateral extensions 106, 107, 134 is laterally retracted with respect to a neighboring vertical sidewall 114, 115 of a respective one of the encapsulants 112, 113. Furthermore, each respective of the encapsulants 112, 113 laterally covers the respective lateral extension 106, 107, 134. During separating the obtained multi-package structure into the individual packages 100, a mechanical sawing blade (not shown) may saw through the encapsulant structure 130 and through the tie bars 122, 123, 150, 151, 156. In contrast to this, the retracted oblong structures 106, 107, 134 are prevented from sawing, thereby avoiding burrs. Also the vertical sidewalls 114, 115 of the encapsulants 112, 113 may be formed and defined by said mechanically sawing. In contrast to this, the other slanted sidewalls 128, 129 of the encapsulants 112, 113 are defined by a slanted sidewall of an encapsulant tool cavity, i.e. by a mold process. The lead sections 124, 126 extending beyond the encapsulants 112, 113 and being electrically coupled with the carriers 102, 103 and/or the electronic components 110, 111 may be separated from spatially adjacent lead sections of other structures such as the one shown in FIG. 3 and FIG. 4 (see for instance FIG. 13) by punching. Advantageously, said punching may be executed before said sawing so that the mechanical integrity provided by the oblong encapsulant structure(s) 130 may be maintained almost until the end of the manufacturing process.

Beneficially, the mold ears or lateral extensions 106, 107, 134 maintain stability and avoid tilting of the die pad-type component mounting areas 104, 105 during encapsulation. According to FIG. 1 to FIG. 4, the encapsulation tool pins 108, 109, 136 keep pressing on the respective lateral extensions 106, 107, 134 until the end of the encapsulation process. The tie bars 122, 123, 150, 151, 156 provide additional stability.

Reference signs 158 in FIG. 1 show vertical side edges of the package 100 defined by sawing, whereas reference signs 160 in FIG. 1 show slanted side edges of the package 100 defined by a mold cavity and by punching lead sections 124, 126.

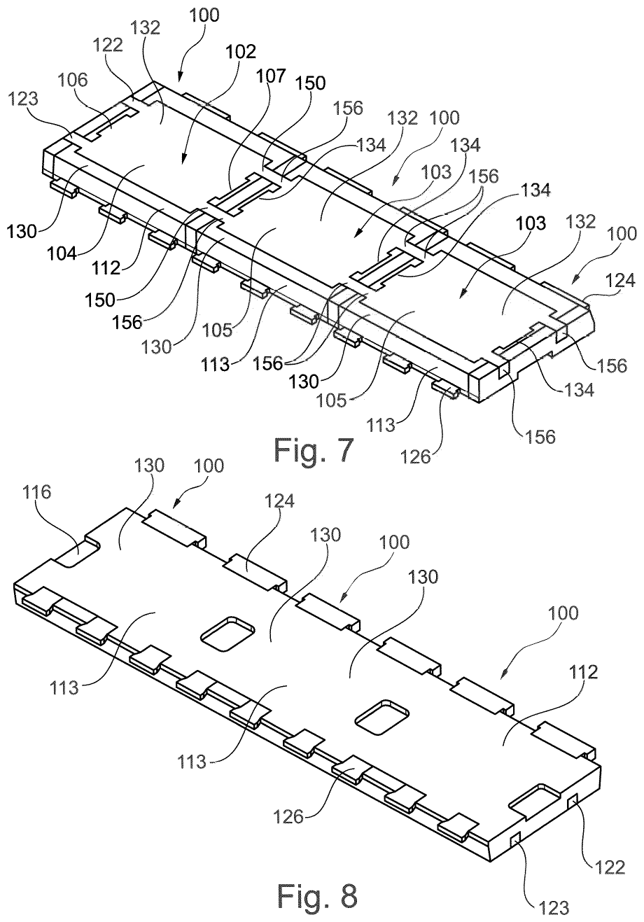

FIG. 5 illustrates a three-dimensional back view of a package 100 according to another exemplary embodiment. FIG. 6 illustrates a three-dimensional front view of the package 100 according to FIG. 5. FIG. 7 illustrates a three-dimensional front view of a structure obtained during manufacturing a package 100 according to FIG. 5 and FIG. 6. FIG. 8 illustrates a three-dimensional back view of a structure obtained during manufacturing a package 100 according to FIG. 5 and FIG. 6.

The embodiment of FIG. 5 to FIG. 8 differs from the embodiment according to FIG. 1 to FIG. 4 in particular in that, according to FIG. 5 to FIG. 8, each of the lateral extensions 106, 107, 134 is vertically separated from the recess 116 by the encapsulant 112. In other words, the lateral extensions 106, 170, 134 are not exposed in the recesses 116 in the embodiment of FIG. 5 to FIG. 8, but are covered with encapsulant material. Thus, the bottom surface of the recesses 116 is defined by encapsulant material only according to FIG. 5 to FIG. 8.

This may be achieved by modifying the above described manufacturing method in that, according to FIG. 5 to FIG. 8, the encapsulation tool pins 108, 109, 136 press on the lateral extensions 106, 107, 134 only during a first part of an encapsulation process and are retracted during a second part of the encapsulation process before curing of encapsulant 112 is completed. For instance, the encapsulation tool pins 108, 109, 136 may be lifted during transfer molding (for instance after 50% of the most process). Consequently, not fully cured and still flowable encapsulant material may fill part of the recesses 116 to thereby cover lateral extensions 106, 107, 134. This will lead to recesses 116 in the encapsulants 112, 113 with the lateral extensions 106, 107, 134 being vertically separated from the respective recess 116 by the respective encapsulant 112, 113.

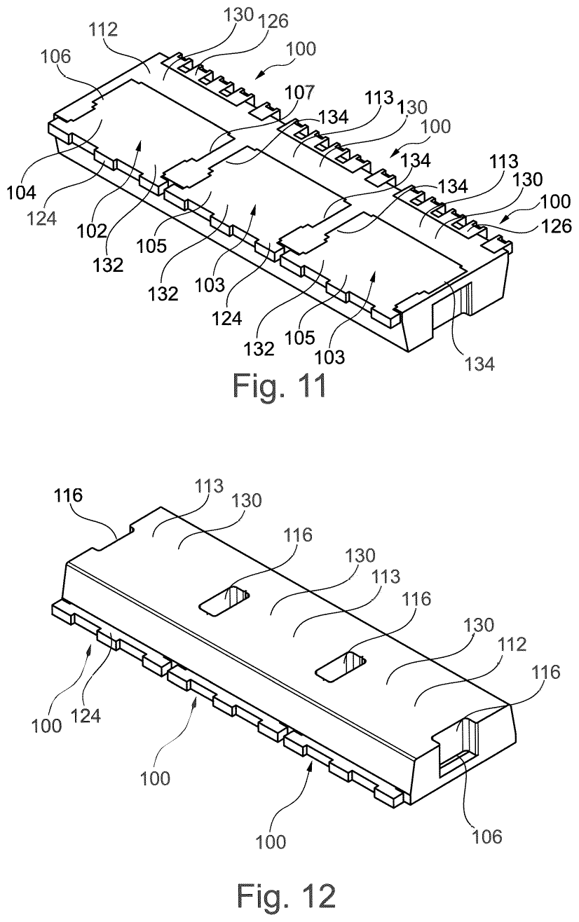

FIG. 9 illustrates a three-dimensional back view of a package 100 according to another exemplary embodiment. FIG. 10 illustrates a three-dimensional front view of the package 100 according to FIG. 9. FIG. 11 illustrates a three-dimensional front view of a structure obtained during manufacturing a package 100 according to FIG. 9 and FIG. 10. FIG. 12 illustrates a three-dimensional back view of a structure obtained during manufacturing a package 100 according to FIG. 9 and FIG. 10.

The embodiment of FIG. 9 to FIG. 12 differs from the embodiment according to FIG. 1 to FIG. 4 in particular in that, according to FIG. 9 to FIG. 12, no tie bars 122, 123, 150, 151, 156 are foreseen. In other words, the packages 100 according to FIG. 9 to FIG. 12 are tie bar-less packages 100. Consequently, the vertical sidewalls 114, 115 are formed exclusively by the encapsulants 112, 113 according to FIG. 9 to FIG. 12.

The sawing process for separating the individual packages 100 according to FIG. 9 to FIG. 12 is particularly simple, since only sawing through mold compound is sufficient. Stability of the die pad-type component mounting areas 104, 105 during encapsulation is accomplished only by the lateral extensions 106, 107, 134 cooperating with the encapsulation tool pins 108, 109, 136.

FIG. 13 illustrates a plan view of a structure obtained during manufacturing a package 100 according to an exemplary embodiment. FIG. 14 illustrates different views of a package 100 obtained from a structure according to FIG. 13.

FIG. 13 corresponds to an embodiment of manufacturing packages 100 as described above referring to FIG. 1 to FIG. 4. FIG. 13 shows that carriers 102, 103 are arranged as integrally formed carrier structures 132 in rows and columns, wherein a respective integrally formed bar-shaped encapsulant structure 130 may be formed for each row or for each column.

The illustrated embodiment relates to a clip package which can be manufactured in a low effort fashion with high density based on a leadframe architecture. With the illustrated batch manufacturing architecture, 144 packages 100 may be manufactured.

On the top side of FIG. 14, a cross-sectional view of a corresponding package 100 is shown. On the bottom side of FIG. 14, a transparent plan view of such a package 100 is illustrated.

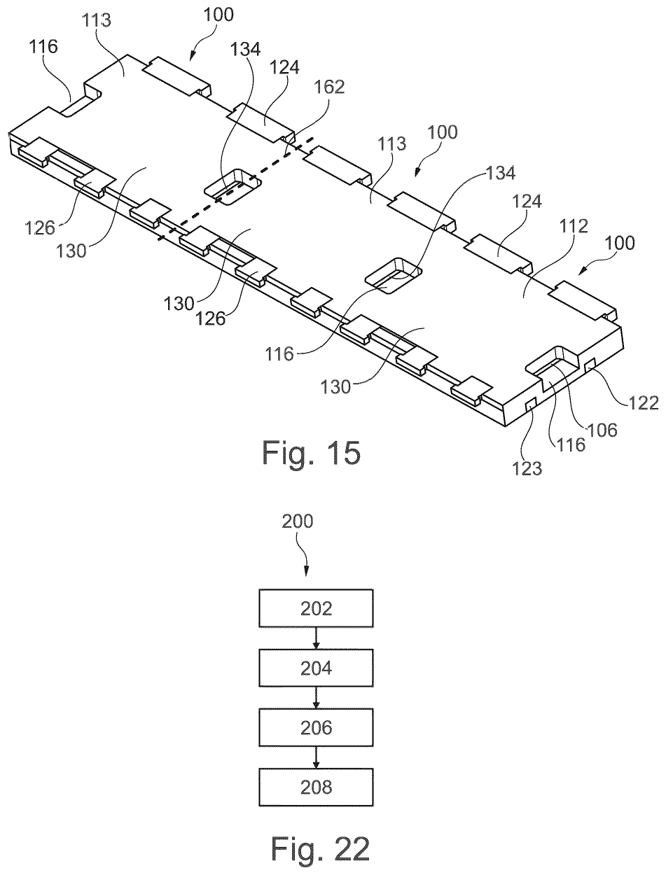

FIG. 15 illustrates a three-dimensional back view of a part of the structure according to FIG. 13. Furthermore, the structure shown in FIG. 15 corresponds to the one shown in FIG. 4.

FIG. 15 shows a sawing line 162 along which the multi-package structure of FIG. 15 may be separated by sawing for obtaining individual packages 100.

With the described embodiment, it may be possible to maintain the full aid of the tie bars 122, 123, 150, 151, 156 for obtaining good planarity of the die pad-type component mounting areas 104, 105. This may lead to a controlled total stack height. During molding, it may be advantageous to hold the large die pads to avoid tilt to thereby prevent mold flash or bleed. The addition of the mold ear-type lateral extensions 106, 107, 134 for clamping by a pin hold may mitigate mold flash risk and may at the same time eliminate the occurrence of sawing burrs.

The illustrated recesses 116 are openings created from the mold pins or clamp holding the mold ears during molding.

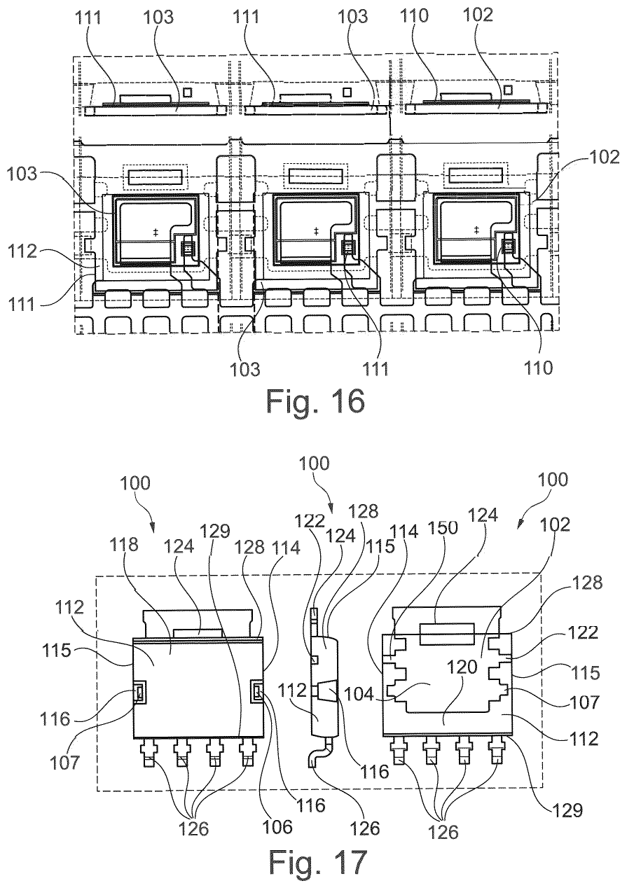

FIG. 16 illustrates a side view (see top) and a plan view (see bottom) of a structure obtained during manufacturing a package 100 according to an exemplary embodiment. FIG. 17 illustrates different views of a package 100 obtained from a structure according to FIG. 16. The embodiment of FIG. 16 and FIG. 17 relates to a smaller version of the packages 100 according to FIG. 1 to FIG. 4. Also this embodiment provides a package 100 configured to eliminate sawing burrs. Again, recesses 116 show openings created from mold pins or a clamp holding the mold ears during moulding.

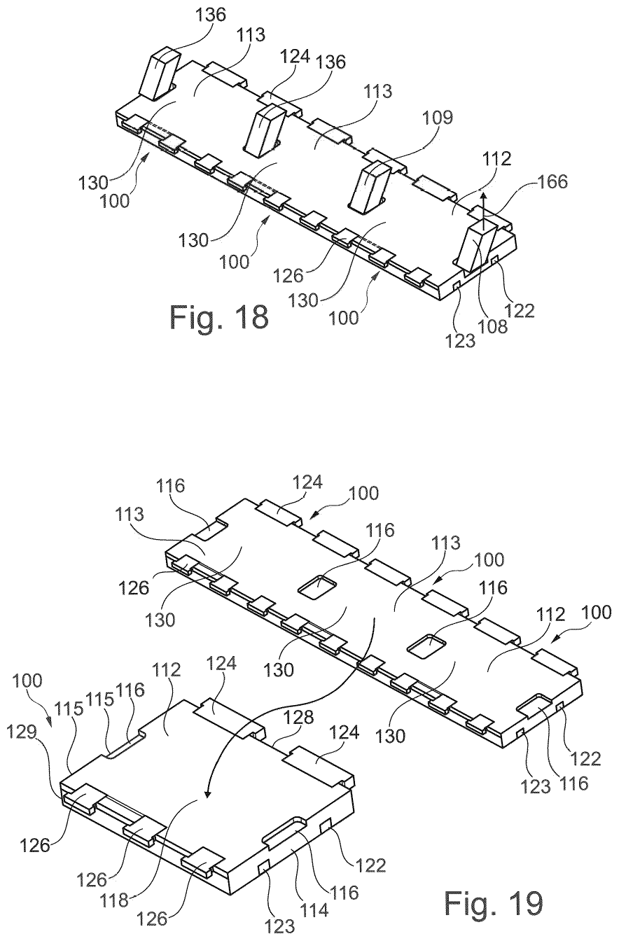

FIG. 18 illustrates a three-dimensional back view of a structure obtained during manufacturing a package 100 according to an exemplary embodiment. FIG. 19 illustrates a package 100 obtained from the structure according to FIG. 18. The configuration of the package 100 of FIG. 19 corresponds to the embodiment of FIG. 5 to FIG. 8.

In particular, FIG. 18 shows encapsulation tool pins 108, 109, 136 which may press down lateral extensions 106, 107, 134 during part of an encapsulation process to avoid bleeding of encapsulant material to an opposing side of connected component mounting areas 104, 105. When said part of the encapsulation process is completed, the encapsulation tool pins 108, 109, 136 may be lifted, as indicated by reference sign 166. When the encapsulation process is not yet completed at the time of lifting, the thereby exposed lateral extensions 106, 107, 134 may be covered by a skin of material of the encapsulant 112, 113, wherein recesses 116 in the encapsulants 112, 113 may nevertheless remain due to the temporary presence of the encapsulation tool pins 108, 109, 136. During molding, retractable pins can thus also be used on the mold ears and/or the tie bars. A burr-free package 100 may be achieved. The recesses 116 constitute retractable pin imprints or marks after retracting at certain height.

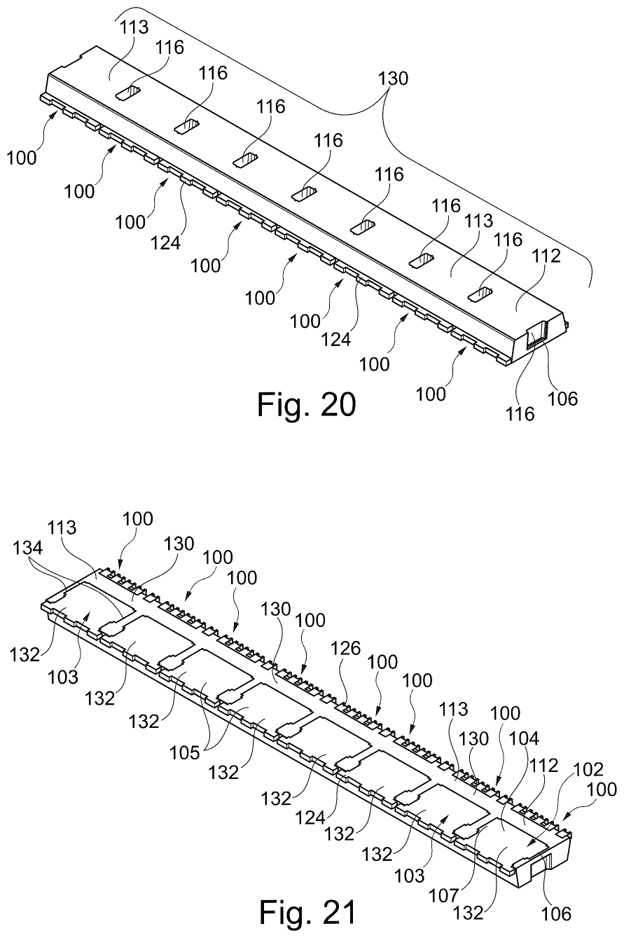

FIG. 20 illustrates a three-dimensional back view of a structure obtained during manufacturing a package 100 according to an exemplary embodiment. FIG. 21 illustrates a three-dimensional front view of the structure according to FIG. 20. This embodiment corresponds to the formation of tie bar-less packages 100 according to the above-described embodiment of FIG. 9 to FIG. 12. Again, the recesses 116 form openings created from the mold pins or a clamp holding the mold ears during molding.

FIG. 22 illustrates a flowchart 200 of a method of manufacturing a package 100 according to an exemplary embodiment. The reference signs used for the following description of said manufacturing method relate to the embodiments of FIG. 1 and FIG. 21.

Referring to a block 202, the method comprises providing a carrier 102 comprising a component mounting area 104 from which a lateral extension 106 extends.

Referring to a block 204, the method comprises mounting an electronic component 110 on the component mounting area 104.

Referring to a block 206, the method comprises encapsulating at least part of the electronic component 110 and part of the carrier 102 by an encapsulant 112, wherein the lateral extension 106 is clamped by an encapsulant tool pin 108 during at least part of the encapsulating.

Referring to a block 208, the method comprises adjusting the encapsulating so that the lateral extension 106 is laterally retracted with respect to a neighboring vertical sidewall 114 of the encapsulant 112, and so that the encapsulant 112 laterally covers the lateral extension 106.

It should be noted that the term “comprising” does not exclude other elements or features and the “a” or “an” does not exclude a plurality. Also, elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, comprising:
a carrier comprising a component mounting area from which a lateral extension extends, the lateral extension being configured for being clamped by an encapsulant tool pin during encapsulation;
an electronic component mounted on the component mounting area; and
an encapsulant encapsulating at least part of the electronic component and part of the carrier; and
wherein the lateral extension is laterally retracted with respect to a neighboring vertical sidewall of the encapsulant, and wherein the encapsulant laterally covers the lateral extension.

2. The package according to claim 1, wherein the carrier comprises a further lateral extension extending from the component mounting area and configured for being clamped by a further encapsulant tool pin during encapsulation, wherein the further lateral extension is laterally retracted with respect to a neighboring further vertical sidewall of the encapsulant, and wherein the encapsulant laterally covers the further lateral extension.

3. The package according to claim 2, wherein the lateral extension and the further lateral extension extend from opposing sides of the component mounting area and are laterally retracted with respect to opposing vertical sidewalls of the encapsulant.

4. The package according to claim 1, wherein the encapsulant has a recess in the vertical sidewall extending vertically up to only one of two opposing main surfaces of the package.

5. The package according to claim 4, wherein the lateral extension is exposed in the recess.

6. The package according to claim 4, wherein the lateral extension is vertically separated from the recess by the encapsulant.

7. The package according to claim 1, comprising at least one tie bar extending from the component mounting area and being exposed at the vertical sidewall of the encapsulant.

8. The package according to claim 7, comprising at least one of the following features:
wherein the lateral extension extends between two tie bars extending from the component mounting area; and
wherein the lateral extension has a smaller length than and/or a larger width than and/or the same thickness as the at least one tie bar.

9. The package according to claim 1, configured as tie bar-less package.

10. The package according to claim 1, comprising at least one of the following features:
wherein the vertical sidewall is formed exclusively by the encapsulant, or exclusively by the encapsulant and at least one tie bar;
comprising one or more electrically conductive lead sections, in particular at least one of which being integrally formed with the component mounting area and/or at least one of which being formed separately from the component mounting area, extending out of the encapsulant at one or two slanted sidewalls of the encapsulant, said one or two slanted sidewalls in particular having a molded texture;
wherein a main surface of the component mounting area facing away from the electronic component is exposed with respect to the encapsulant; and
wherein the vertical sidewall has a sawn texture.

11. A method of manufacturing a package, the method comprising:
providing a carrier comprising a component mounting area from which a lateral extension extends;
mounting an electronic component on the component mounting area;
encapsulating at least part of the electronic component and part of the carrier by an encapsulant, wherein the lateral extension is clamped by an encapsulant tool pin during at least part of the encapsulating; and
adjusting the encapsulating so that the lateral extension is laterally retracted with respect to a neighboring vertical sidewall of the encapsulant, and so that the encapsulant laterally covers the lateral extension.

12. The method according to claim 11, wherein the method comprises:
providing an oblong carrier structure comprising the carrier and at least one additional carrier comprising at least one additional component mounting area from which at least one additional lateral extension extends;
mounting at least one additional electronic component on the at least one additional component mounting area;
encapsulating at least part of the at least one additional electronic component and part of the at least one additional carrier by an oblong encapsulant structure to which also said encapsulant belongs, wherein the at least one additional lateral extension is clamped by at least one additional tool pin and/or by said encapsulant tool pin during at least part of the encapsulating; and
separating an obtained structure into individual packages each comprising a respective one of said carriers, a respective one of said electronic components, and a part of said encapsulant structure as a respective encapsulant, so that each of the lateral extensions is laterally retracted with respect to a neighboring vertical sidewall of a respective one of the encapsulants, and so that each respective of the encapsulants laterally covers the respective lateral extension.

13. The method according to claim 12, wherein the method comprises
connecting the carrier with the at least one additional carrier by at least one tie bar; and
separating the obtained structure into the individual packages by sawing through the encapsulant structure and through the at least one tie bar.

14. The method according to claim 11, wherein the method comprises forming the vertical sidewall of the encapsulant by mechanically sawing.

15. The method according to claim 11, wherein the method comprises forming another slanted sidewall of the encapsulant by a slanted sidewall of an encapsulant tool cavity.

16. The method according to claim 11, wherein the method comprises punching lead sections extending beyond the encapsulant and being electrically coupled with the carrier and/or the electronic component.

17. The method according to claim 14, wherein the method comprises carrying out the punching before the sawing.

18. The method according to claim 11, wherein the method comprises clamping on the lateral extension by the encapsulant tool pin during encapsulation so that the component mounting area is pressed onto a counter surface of an encapsulation tool.

19. The method according to claim 18, wherein the method comprises clamping on the lateral extension by the encapsulant tool pin during an entire encapsulation process so that a recess is formed in the encapsulant in which recess the lateral extension is exposed.

20. The method according to claim 18, wherein the method comprises clamping on the lateral extension by the encapsulant tool pin during a first part of an encapsulation process and retracting the encapsulant tool pin during a second part of the encapsulation process so that a recess is formed in the encapsulant with the lateral extension being vertically separated from the recess by the encapsulant.
